(19) United States
(12) Patent Application Publication
(10) Pub. No.: US 2026/0031594 A1
(43) Pub. Date: Jan. 29, 2026

(54) VERTICAL-CAVITY SURFACE-EMITTING LASER DEVICE HAVING TRANSPARENT CONDUCTIVE LAYERS

(71) Applicant: HLJ TECHNOLOGY CO., LTD., Hsinchu County (TW)

(72) Inventors: YEN-CHUN TSENG, Hsinchu County (TW); BING-CHENG LIN, Hsinchu County (TW); LI-WEN LAI, Taoyuan City (TW); LI-HUNG LAI, Taoyuan City (TW)

(21) Appl. No.: 18/966,140

(22) Filed: Dec. 3, 2024

(30) Foreign Application Priority Data
Jul. 29, 2024 (TW) 113128022

(51) Int. Cl. H01S 5/042; H01S 5/183

(52) U.S. Cl. CPC H01S 5/04253; H01S 5/04256; H01S 5/18347; H01S 5/18361; H01S 5/18394

(57) ABSTRACT

A vertical-cavity surface-emitting laser device having transparent conductive layers includes a substrate, a first reflective layer, a plurality of active light-emitting layers, a plurality of second reflective layers, and a plurality of transparent conductive layers. The first reflective layer is disposed on a top surface and includes a base portion and a plurality of reflective portions. The reflective portions are arranged on the base portion at intervals, and any two adjacent reflective portions are spaced apart by a distance. A plurality of exposed surfaces are defined on a region of the surface of the first reflective layer without the reflective portions. The active light-emitting layers are correspondingly and respectively disposed on the reflective portions. The second reflective layers are correspondingly and respectively disposed on the active light-emitting layers. The transparent conductive layers are correspondingly and respectively disposed on the second reflective layers.

### CROSS-REFERENCE TO RELATED PATENT APPLICATION

This application claims the benefit of priority to Taiwan Patent Application No. 113128022, filed on Jul. 29, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a vertical-cavity surface-emitting laser device, and more particularly to a vertical-cavity surface-emitting laser device having transparent conductive layers.

### BACKGROUND OF THE DISCLOSURE

Existing vertical common-cavity surface emitting laser devices include at least an active layer for generating photons, and an upper Bragg reflector and a lower Bragg reflector disposed at the two sides of the active layer. By applying a voltage, a current is poured into the active layer and excites the photons. The upper and lower Bragg reflectors form a vertical resonance cavity, and then the laser beam is emitted from the surface of a component.

In the existing vertical common-cavity surface emitting lasers, oxidation process is generally used for forming an oxidation layer with high resistivity in the upper Bragg reflector, so as to limit the region through which the current passes. However, the oxidation process for forming the oxidation layer and limiting the current requires higher costs and larger mesa size, which influences the light-emitting effect of the laser devices.

For the oxidation layer formed by the oxidation process, since the lattice mismatch and the difference between the thermal expansion coefficients of the oxidation layer and the semiconductor material constituting the upper Bragg reflector are large, the oxidation layer is prone to have defects (such as cracks) due to internal stress, which further reduces the yield of the process, influences the light-emitting effect, and reduces the reliability of the component.

Therefore, how to improve the light-emitting effect of the vertical common-cavity surface emitting lasers through improvements on structural designs to overcome the above problems has become an important issue to be addressed in the relevant industry.

### SUMMARY OF THE DISCLOSURE

In response to the above-referenced technical inadequacies, the present disclosure provides a vertical-cavity surface-emitting laser device.

In order to solve the above-mentioned problems, one of the technical aspects adopted by the present disclosure is to provide a vertical-cavity surface-emitting laser device having transparent conductive layers. The vertical-cavity surface-emitting laser device includes: a substrate, an electrode layer, a first reflective layer, a plurality of active light-emitting layers, a plurality of second reflective layers, and a plurality of transparent conductive layers. The substrate has a top surface and a bottom surface. The electrode layer is disposed on the bottom surface. The first reflective layer is disposed on the top surface, and includes a base portion and a plurality of reflective portions. The reflective portions are arranged on the base portion at intervals, any two adjacent ones of the reflective portions are spaced apart by a distance, and a plurality of exposed surfaces are defined on a region of a surface of the first reflective layer that does not have the reflective portions. The active light-emitting layers are respectively disposed on and correspond to the reflective portions. The second reflective layers are respectively disposed on and correspond to the active light-emitting layers. The transparent conductive layers are respectively disposed on and correspond to the second reflective layers.

In one of the possible or preferred embodiments, the vertical-cavity surface-emitting laser device having transparent conductive layers further includes a protective layer. The protective layer has a plurality of bottom portions, a plurality of side portions, and a plurality of extending portions. Two sides of each of the bottom portions are respectively connected to one end of the side portion, and each of the extending portions is connected to another end of the side portion. Each of the bottom portions is configured to cover each of the exposed surfaces, and each of the side portions is configured to cover on a same side of each of the reflective portions, each of the active light-emitting layers, and each of the second reflective layers. Each of the extending portions is disposed between a corresponding one of the transparent conductive layers and a corresponding one of the second reflective layers. Corresponding to one of the transparent conductive layers, a light aperture is defined between the two adjacent ones of the extending portions.

In one of the possible or preferred embodiments, the vertical-cavity surface-emitting laser device having transparent conductive layers further includes a plurality of connecting portions. A material of each of the connecting portions is identical to each of the transparent conductive layers, and two ends of each of the connecting portions are connected to one of the transparent conductive layers and an adjacent one of the transparent conductive layers, respectively. Each of the connecting portions is configured to cover on two opposite side portions and to cover the corresponding bottom portion.

In one of the possible or preferred embodiments, a length of each of the active light-emitting layers in a first direction is greater than or equal to an aperture diameter of each of the light apertures in the first direction.

In one of the possible or preferred embodiments, the vertical-cavity surface-emitting laser device having transparent conductive layers further includes a protective layer. The protective layer has a plurality of bottom portions, a plurality of side portions, and a plurality of extending portions. Two sides of each of the bottom portions are respectively connected to one end of the side portion, and each of the extending portions is connected to another end of the side portion. Each of the bottom portions is configured to cover on each of the exposed surfaces, and each of the side portions is configured to cover on the same side of each of the reflective portions, each of the active light-emitting layers, each second reflective layer, and each of the transparent conductive layers. Each extending portion is disposed on a corresponding one of the transparent conductive layers. Corresponding to one of the transparent conductive layers, a light aperture is defined between the two adjacent ones of the extending portions.

In one of the possible or preferred embodiments, the length of each of the active light-emitting layers in a first direction is equal to the aperture diameter of each of the light apertures in the first direction.

In one of the possible or preferred embodiments, the vertical-cavity surface-emitting laser device having transparent conductive layers further includes a plurality of fillers. The fillers are made of a conductive material or a dielectric material, and each of the fillers includes a filling portion and two extending portions. Corresponding to each of the exposed surfaces, a first side surface and a second side surface are defined on lateral sides of the reflective portion, the active light-emitting layer, and the second reflective layer. The exposed surface, the first side surface, and the second side surface are configured to form a sink. Each of the fillers is configured to fill each of the sinks. Two of the extending portions are respectively connected to the opposite two sides of the filling portion, and each of the two extending portions is disposed between the corresponding transparent conductive layer and the second reflective layer. Corresponding to the transparent conductive layer, a light aperture is defined between the two adjacent extending portions.

In one of the possible or preferred embodiments, the vertical-cavity surface-emitting laser device having transparent conductive layers further includes a plurality of fillers. The fillers are made of a conductive material or a dielectric material, and each of the fillers has a filling portion and two extending portions. Corresponding to each of the exposed surfaces, a first sider surface and a second side surface are defined on lateral sides of the reflective portion, the active light-emitting layer, and the second reflective layer, and the exposed surface, the first side surface, and the second side surface form a sink. Each of the fillers is configured to fill each of the sinks. Two of the extending portions are respectively connected to the opposite two sides of the filling portion, and each of the extending portions is disposed on each of the transparent conductive layers. Corresponding to the transparent conductive layer, a light aperture is defined between the two adjacent extending portions.

In one of the possible or preferred embodiments, the number of the electrode layer is plural, the positions thereof are corresponding to each of the reflective portions, and the length of each of the electrode layers in the first direction is less than or equal to the length of each of the transparent conductive layers in the first direction.

In one of the possible or preferred embodiments, the length of each of the transparent conductive layers in the first direction is less than or equal to the length of each of the reflective portions in the first direction.

In one of the possible or preferred embodiments, the transparent conductive layer is a metal thin film or an indium tin oxide layer.

Therefore, in the vertical-cavity surface-emitting laser device having transparent conductive layers provided by the present disclosure, the electric current is transmitted through the transparent conductive layers, and the vertical-cavity surface-emitting laser device does not have a current limiting layer (particularly an oxidation layer formed by the oxidation process). In this way, the vertical-cavity surface-emitting laser device will not have the defects generated in the oxidation process, such that the quality of the vertical-cavity surface-emitting laser devices can be improved.

In addition, in the vertical-cavity surface-emitting laser device having transparent conductive layers provided by the present disclosure, because there is no oxidation layer formed by the oxidation process, the vertical-cavity surface-emitting laser device having a mesa, a light-emitting surface, or a light aperture in small sizes can be achieved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a cross-sectional view of a vertical-cavity surface-emitting laser device having transparent conductive layers according to one embodiment of the present disclosure;

FIG. 2 is another cross-sectional view of the vertical-cavity surface-emitting laser device having transparent conductive layers according to one embodiment of the present disclosure;

FIG. 3 is yet another cross-sectional view of the vertical-cavity surface-emitting laser device having transparent conductive layers according to one embodiment of the present disclosure;

FIG. 4 is still another cross-sectional view of the vertical-cavity surface-emitting laser device having transparent conductive layers according to one embodiment of the present disclosure;

FIG. 5 is still yet another cross-sectional view of the vertical-cavity surface-emitting laser device having transparent conductive layers according to one embodiment of the present disclosure;

FIG. 6 is still yet another cross-sectional view of the vertical-cavity surface-emitting laser device having transparent conductive layers according to one embodiment of the present disclosure; and

FIG. 7 is still yet another cross-sectional view of the vertical-cavity surface-emitting laser device having transparent conductive layers according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiments

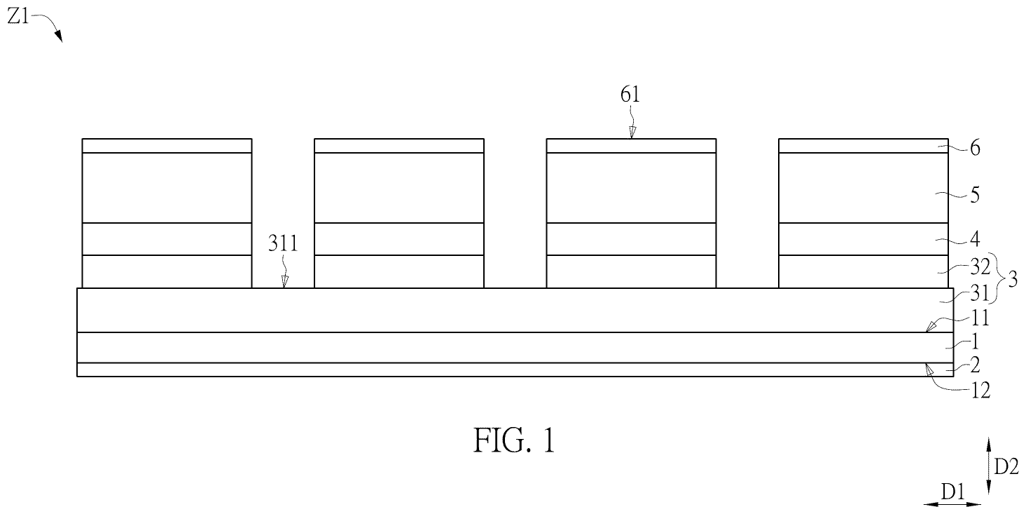

Reference is made to FIG. 1, which is a cross-sectional view of a vertical-cavity surface-emitting laser device Z1 having transparent conductive layers according to an embodiment of the present disclosure. The vertical-cavity surface-emitting laser device Z1 having transparent conductive layers includes: a substrate 1, an electrode layer 2, a first reflective layer 3, a plurality of active light-emitting layers 4, a plurality of second reflective layers 5, and a plurality of transparent conductive layers 6.

The substrate 1 has a top surface 11 and a bottom surface 12. The electrode layer 2 is disposed on the bottom surface 12. The first reflective layer 3 is disposed on the top surface 11, and includes a base portion 31 and a plurality of reflective portions 32 arranged on the base portion 31 at intervals. Any two adjacent ones of the reflective portions 32 are spaced apart by a distance. A plurality of exposed surfaces 311 are defined on a region of a surface of the first reflective layer 3 that does not have the reflective portions 32. The active light-emitting layers 4 are respectively disposed on and correspond to the reflective portions 32. The second reflective layers 5 are respectively disposed on and correspond to the active light-emitting layers 4. The transparent conductive layers 6 are respectively disposed on and correspond to the second reflective layers 5.

The substrate 1 can be of an insulator material or semiconductor material. For example, the insulator material can be sapphire, and the semiconductor material can be silicon, germanium, silicon carbide, or Group III-V semiconductors. Group III-V semiconductors can be, for example, gallium arsenide (GaAs), indium phosphide (InP), aluminum nitride (AlN), indium nitride (InN), or gallium nitride (GaN). According to certain examples, the electrode layer 2 is a metal or an alloy, and is disposed on the bottom surface 12 of the substrate 1. According to certain examples, the first reflective layer 3 and the second reflective layers 5 are distributed Bragg reflector (DBR) formed by alternately stacking two types of thin films having different refractive indices, such that the beam having a predetermined wavelength reflects and resonates. According to certain examples, the materials of the first reflective layer 3 and the second reflective layers 5 can be the doped Group III-V compound semiconductors. According to certain further examples, the first reflective layer 3 and the second reflective layers 5 can respectively be different conductive types. For example, the first reflective layer 3 is an N-type semiconductor layer, and the second reflective layers 5 are P-type semiconductor layers. According to certain examples, the transparent conductive layers 6 are indium tin oxide layers which have the properties of being light-transmissive and electrically conductive, and can be used for electrical connection. In certain examples, another electrode layer (or an electrical contact) can be disposed or not be disposed on the surfaces of the transparent conductive layers 6. According to certain further examples, the transparent conductive layers 6 can also be metal thin films, and when the metal thin film reaches a specific thinness, the metal thin film can also be translucent, and can be used in the vertical-cavity surface-emitting laser devices.

According to certain examples, the base portion 31 and the reflective portions 32 are formed by etching the first reflective layer 3, and the reflective portions 32 are arranged on the base portion 31 as an array. For example, after disposing the first reflective layer 3 (configured to have a specific thickness), the active light-emitting layers 4, and the second reflective layers 5, the second reflective layers 5, the active light-emitting layers 4, and the first reflective layer 3 are sequentially etched in a vertical direction D2, and the base portion 31 and the reflective portions 32 are formed in the first reflective layer 3. However, the present disclosure is not limited thereto. In certain examples, the base portion 31 can first be arranged, and then a reflective layer is disposed on the base portion 31, and the plurality of reflective portions 32 are then formed by etching the reflective layer.

According to certain examples, the surface of the transparent conductive layer 6 is a light-emitting surface 61, and the length of the light-emitting surface 61 is less than or equal to 10 μm. In other words, in certain examples, the length of the mesa in the first direction D1 is less than or equal to 10 μm. The above-mentioned mesa includes the reflective portion 32, the active light-emitting layer 4, the second reflective layer 5, and the transparent conductive layer 6. Based on the design of this structure, since the size of the light-emitting surface 61 (or a light aperture O, referring to the descriptions below) is small, the light beam can be emitted in a nearly straight manner, which has the effect of concentrating the light beam.

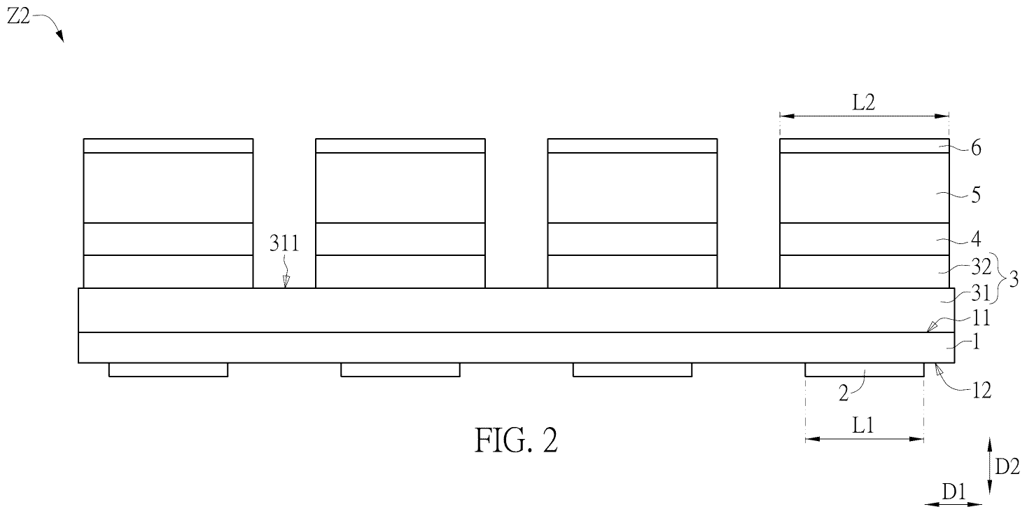

Reference is made to FIG. 2, which is a cross-sectional view of a vertical-cavity surface-emitting laser device Z2 having transparent conductive layers according to an embodiment of the present disclosure. In this embodiment, the number of the electrode layer 2 is two, and the positions of the two electrode layers 2 correspond to each of the reflective portions 32. A length L1 of each of the electrode layers 2 in the first direction D1 is less than or equal to the length of each of the transparent conductive layers 6 in the first direction D1. Since the side surface formed by same sides of the reflective portions 32, active light-emitting layers 4, second reflective layers 5, and transparent conductive layers 6 may have defects, it is disadvantageous for the current to flow through. Therefore, by the design of the length L1 of the electrode layer 2 being less than a length L2 of the transparent conductive layer 6 (that is, less than the length of the mesa), the current is prone to be concentrated and flow to the electrode layer 2. Furthermore, in certain examples, the length of the transparent conductive layer 6 in the first direction D1 is less than or equal to the length of the reflective portion 32 in the first direction D1.

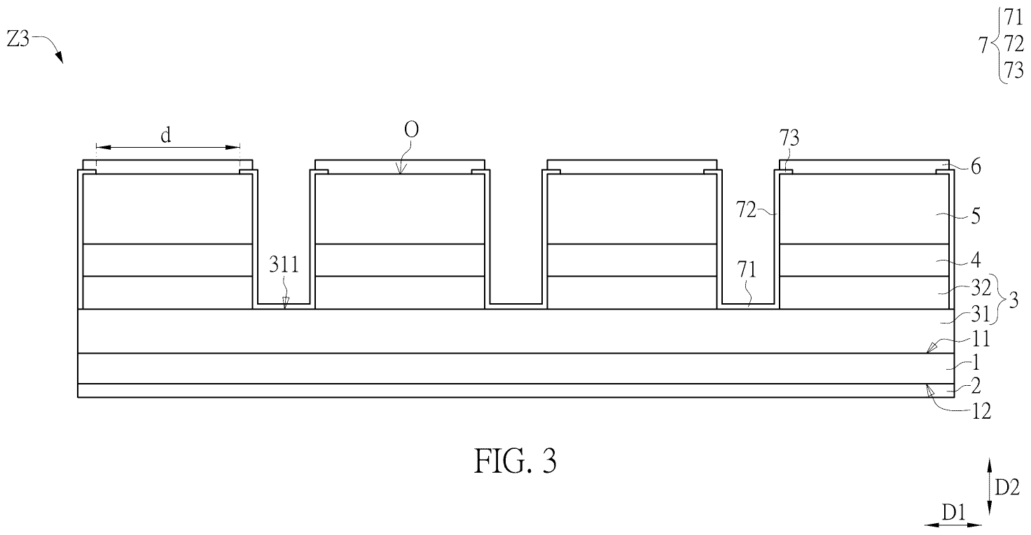

Reference is made to FIG. 3, which is a cross-sectional view of a vertical-cavity surface-emitting laser device Z3 having transparent conductive layers according to an embodiment of the present disclosure. In this embodiment, the vertical-cavity surface-emitting laser device Z3 having transparent conductive layers further includes a protective layer 7, and the protective layer has a plurality of bottom portions 71, a plurality of side portions 72, and a plurality of extending portions 73. Two sides of each of the bottom portions 71 are respectively connected to one end of the side portion 72, and each of the extending portions 73 is connected to another end of the side portion. Each of the bottom portions 71 is configured to cover each of the exposed surfaces 311. Each side portion 72 is configured to cover on the same side of each of the reflective portions 32, each of the active light-emitting layers 4, and each of the second reflective layers 5. Each of the extending portions 73 is disposed between the transparent conductive layer 6 and the second reflective layer 5. Corresponding to the transparent conductive layer 6, a light aperture O is defined between two adjacent ones of the extending portions 73. According to certain examples, the material of the protective layer 7 can be alumina (AlOx), silicon oxide (SiOx), or silicon nitride (SiNx). According to certain examples, an aperture diameter d of the light aperture O is less than 10 um. According to certain examples, to achieve the light beam being emitted in a nearly straight manner from the light aperture O, a length of each of the active light-emitting layers 4 in the first direction D1 is greater than or equal to the aperture diameter d of each of the light apertures O in the first direction D1.

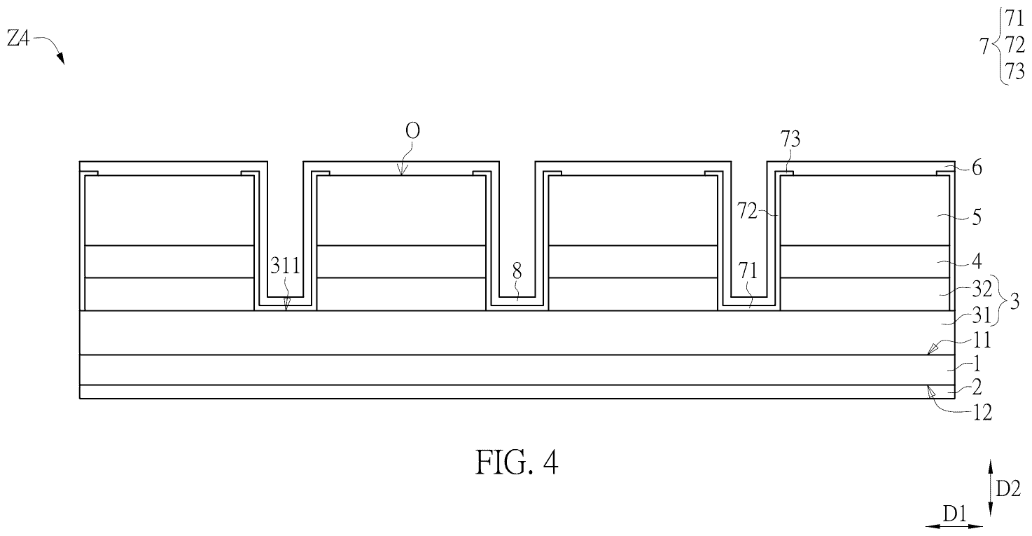

Reference is made to FIG. 4, which is a cross-sectional view of a vertical-cavity surface-emitting laser device Z4 having transparent conductive layers according to an embodiment of the present disclosure. In this embodiment, the vertical-cavity surface-emitting laser device Z4 having transparent conductive layers further includes a plurality of connecting portions 8, and the material of each of the connecting portions 8 is identical to each of the transparent conductive layers 6, and two ends of each of the connecting portions 8 are respectively connected to one of the transparent conductive layers 6 and an adjacent one of the transparent conductive layers 6. Each of the connecting portions 8 is configured to cover on two opposite side portions 72 and to cover the corresponding bottom portion 71. According to certain examples, the connecting portion 8 and the transparent conductive layer 6 are structurally on the same layer. According to the embodiment shown in FIG. 4, in the aspect of manufacturing, the vertical-cavity surface-emitting laser device is easier to manufacture, and the effect of guiding the current is improved.

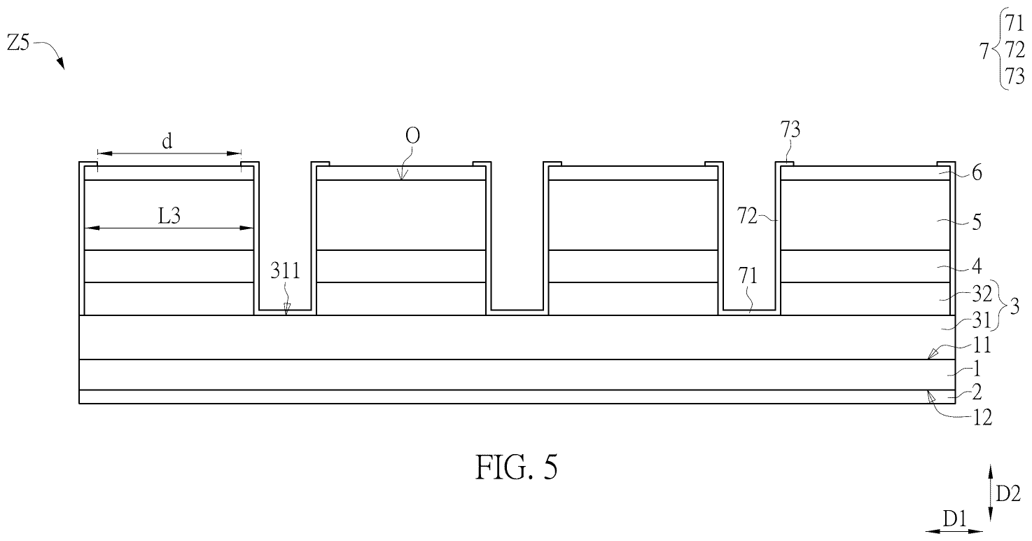

Reference is made to FIG. 5, which is a cross-sectional view of a vertical-cavity surface-emitting laser device Z5 having transparent conductive layers according to an embodiment of the present disclosure. Different from the embodiment shown in FIG. 3, in the embodiment shown in FIG. 5, each of the extending portions 73 is disposed on the transparent conductive layer 6. According to the embodiment of FIG. 5, a length L3 of the active light-emitting layer 4 in the first direction D1 is equal to the aperture diameter d of the light aperture O in the first direction D1.

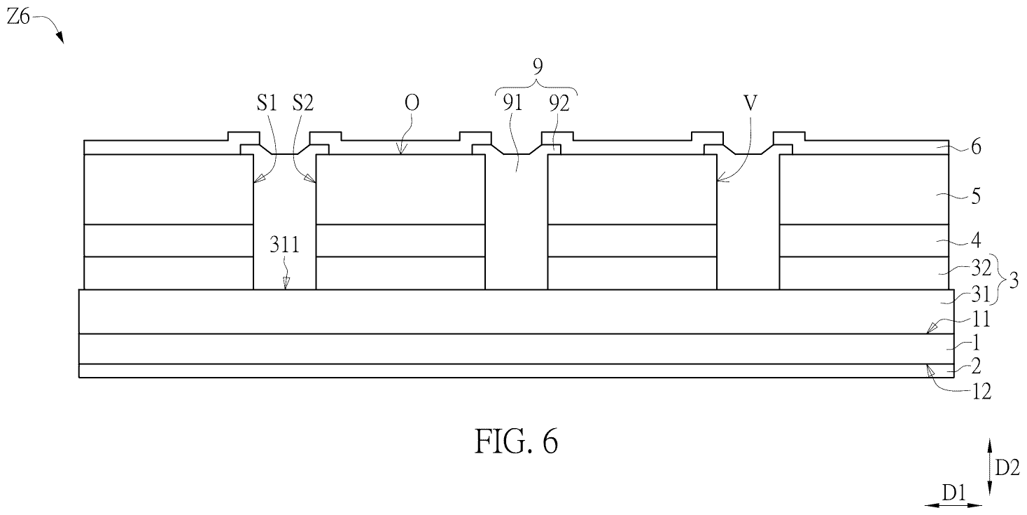

Reference is made to FIG. 6, which is a cross-sectional view of a vertical-cavity surface-emitting laser device Z6 having transparent conductive layers according to an embodiment of the present disclosure. In this embodiment, the vertical-cavity surface-emitting laser device Z6 having transparent conductive layers further includes a plurality of fillers 9, and each of the fillers 9 has a filling portion 91 and two extending portions 92.

Corresponding to each of the exposed surfaces 311, a first side surface S1 and a second side surface S2 are defined on the side surfaces of the reflective portion 32, the active light-emitting layer 4, and the second reflective layer 5. The exposed surface 311, the first side surface S1, and the second side surface S2 form a groove V, and each of the filling portions 91 is filled in each of the grooves V. Two extending portions 92 are respectively connected on two opposite sides of the filling portion 91, and each of the extending portions 92 is disposed between the corresponding one of the transparent conductive layers 6 and the second reflective layer 5. Corresponding to the transparent conductive layer 6, a light aperture O is defined between two extending portions 92.

The fillers 9 are made of conductive materials, and in certain examples, the fillers 9 are metal. The benefit of filling the groove V with metal is that, the heat dissipation effect of the vertical-cavity surface-emitting laser device can be improved, and the effect of consistent flowing direction of the currents (i.e., the currents flow from the transparent conductive layer 6 to the electrode layer 2) can be achieved. Furthermore, according to certain examples, the fillers 9 are made of dielectric material, such as polyimide (PI) resin.

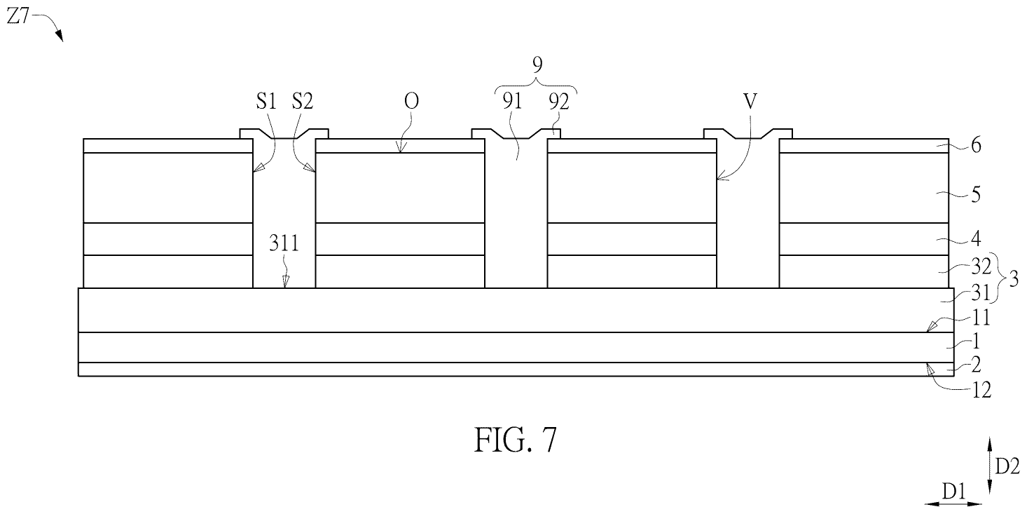

Reference is made to FIG. 7, which is a cross-sectional view of the vertical-cavity surface-emitting laser device having transparent conductive layers according to an embodiment of the present disclosure. Different from the embodiment shown in FIG. 6, the extending portions 92 of the vertical-cavity surface-emitting laser device of the embodiment shown in FIG. 7 are disposed on the transparent conductive layers 6.

### Beneficial Effects of the Embodiments

One advantage of the present disclosure is that, the vertical-cavity surface-emitting laser device provided by the present disclosure does not have a current limiting layer (particularly an oxidation layer formed by the oxidation process). In this way, there is no defect generated from the oxidation process, and thus the quality of the vertical-cavity surface-emitting laser device can be improved.

Furthermore, according to one embodiment of the present disclosure, the size of the mesa of the vertical-cavity surface-emitting laser device is decreased, and a size of the light-emitting surface (i.e., the diameter of the light aperture) is small, such that the light beam can be emitted from the light aperture in a nearly straight manner, and the light is concentrated to improve the light-emitting effect of the vertical-cavity surface-emitting laser device.

Furthermore, according to one embodiment of the present disclosure, the grooves of the vertical-cavity surface-emitting laser device are filled with metal, which can improve the heat dissipation function of the vertical-cavity surface-emitting laser device, guide the current to have a consistent flow, and improve the performance of the vertical-cavity surface-emitting laser device.

In addition, according to one embodiment of the present disclosure, the grooves of the vertical-cavity surface-emitting laser device are filled with dielectric material.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A vertical-cavity surface-emitting laser device, comprising:
a substrate having a top surface and a bottom surface;
at least one electrode layer disposed on the bottom surface;
a first reflective layer disposed on the top surface, wherein the first reflective layer includes a base portion and a plurality of reflective portions, the reflective portions are arranged on the base portion at intervals, any two adjacent ones of the reflective portions are spaced apart by a distance, and a plurality of exposed surfaces are defined on a region of a surface of the first reflective layer that does not have the reflective portions;
a plurality of active light-emitting layers respectively disposed on and corresponding to the reflective portions;
a plurality of second reflective layers respectively disposed on and corresponding to the active light-emitting layers; and
a plurality of transparent conductive layers respectively disposed on and corresponding to the second reflective layers.

2. The vertical-cavity surface-emitting laser device according to claim 1, further comprising a protective layer, wherein the protective layer includes a plurality of bottom portions, a plurality of side portions, and a plurality of extending portions; wherein two sides of each of the bottom portions are respectively connected to one end of the side portion, each of the extending portions is connected to another end of the side portion, and each of the bottom portions is configured to cover each of the exposed surfaces; wherein each of the side portions is configured to cover on a same side of each of the reflective portions, each of the active light-emitting layers, and each of the second reflective layers; wherein each of the extending portions is disposed between a corresponding one of the transparent conductive layers and a corresponding one of the second reflective layers; and wherein, corresponding to one of the transparent conductive layers, a light aperture is defined between two adjacent ones of the extending portions.

3. The vertical-cavity surface-emitting laser device according to claim 2, further comprising a plurality of connecting portions, wherein a material of each of the connecting portions is identical to the transparent conductive layer, and two ends of each of the connecting portions are connected to one of the transparent conductive layers and an adjacent one of the transparent conductive layers, respectively, and each of the connecting portions is configured to cover on two opposite side portions and to cover the corresponding bottom portion.

4. The vertical-cavity surface-emitting laser device according to claim 2, wherein a length of each of the active light-emitting layers in a first direction is greater than or equal to an aperture diameter of each of the light apertures on the first direction.

5. The vertical-cavity surface-emitting laser device according to claim 3, wherein a length of each of the active light-emitting layers on a first direction is greater than or equal to an aperture diameter of each of the light apertures on the first direction.

6. The vertical-cavity surface-emitting laser device according to claim 1, further comprising a protective layer, wherein the protective layer includes a plurality of bottom portions, a plurality of side portions, and a plurality of extending portions; wherein two sides of each of the bottom portions are respectively connected to one end of the side portion, each of the extending portions is connected to another end of the side portion, and each of the bottom portions is configured to cover each of the exposed surfaces;
wherein each of the side portions is configured to cover on a same side of each of the reflective portions, each of the active light-emitting layers, each of the second reflective layers, and each of the transparent conductive layers, each of the extending portions is disposed on one of the transparent conductive layers; and wherein, corresponding to one of the transparent conductive layers, a light aperture is defined between two adjacent ones of the extending portions.

7. The vertical-cavity surface-emitting laser device according to claim 6, wherein a length of each of the active light-emitting layers on a first direction is equal to an aperture diameter of each of the light apertures on the first direction.

8. The vertical-cavity surface-emitting laser device according to claim 1, further comprising a plurality of fillers, wherein each of the fillers is made of a conductive material or a dielectric material, and includes a filling portion and two extending portions; wherein, corresponding to each of the exposed surfaces, a first side surface and a second side surface are defined on lateral sides of the reflective portion, the active light-emitting layer, and the second reflective layer; wherein the exposed surface, the first side surface, and the second side surface are configured to form a sink, and each of the fillers is configured to fill each of the sinks; wherein two of the extending portions are respectively connected to the opposite two sides of the filling portion, and each of the two extending portions is disposed between the corresponding transparent conductive layer and the second reflective layer; and wherein, corresponding to the transparent conductive layer, a light aperture is defined between the two adjacent extending portions.

9. The vertical-cavity surface-emitting laser device according to claim 1, further comprising a plurality of fillers, wherein each of the fillers is made of a conductive material or dielectric material and includes a filling portion and two extending portions; wherein corresponding to each of the exposed surfaces, a first side surface and a second side surface are defined on lateral sides of the reflective portion, the active light-emitting layer, and the second reflective layer; wherein the exposed surface, the first side surface, and the second side surface form a sink, and each of the fillers is configured to fill each of the sinks; wherein two of the extending portions are respectively connected to the opposite two sides of the filling portion, and each of the extending portions is disposed on each of the transparent conductive layers; and wherein corresponding to the transparent conductive layer, a light aperture is defined between the two adjacent extending portions.

10. The vertical-cavity surface-emitting laser device according to claim 1, wherein the electrode layer is plural in quantity, the positions of the electrode layers respectively correspond to each of the reflective portions, and a length of each of the electrode layers on a first direction is less than or equal to a length of each of the transparent conductive layers on the first direction.

11. The vertical-cavity surface-emitting laser device according to claim 10, wherein the length of each of the transparent conductive layers on the first direction is less than or equal to a length of each of the reflective portions on the first direction.

12. The vertical-cavity surface-emitting laser device according to claim 1, wherein the transparent conductive layer is a metal thin film or an indium tin oxide layer.
